(19) United States
(12) Patent Application Publication
(10) Pub. No.: US 2026/0113027 A1
(43) Pub. Date: Apr. 23, 2026

(54) SEMICONDUCTOR DEVICE

(71) Applicant: FUJI ELECTRIC CO., LTD., Kawasaki-shi (JP)

(72) Inventor: Daisuke ISOBE, Matsumoto-city (JP)

(73) Assignee: FUJI ELECTRIC CO., LTD., Kawasaki-shi (JP)

(21) Appl. No.: 19/307,669

(22) Filed: Aug. 22, 2025

(30) Foreign Application Priority Data
Oct. 17, 2024 (JP) 2024-181531

(51) Int. Cl. H03K 17/082; H03K 17/18

(52) U.S. Cl. CPC H03K 17/0822; H03K 17/18; H03K 2217/0081

(57) ABSTRACT

A semiconductor device, including: an output element configured to be connected to a load and to operate the load; a clamp operation detection circuit configured to detect a clamp operation on the load and to output a clamp operation detection signal; an internal power supply instruction circuit configured to receive an input signal for performing switching driving of the output element, an abnormality detection signal indicating an abnormal device state of the semiconductor device and the clamp operation detection signal, and to output a control signal instructing whether to provide an internal power supply based on the input signal, the abnormality detection signal and the clamp operation detection signal; and an internal power supply provision circuit configured to receive the control signal, and to control provision of the internal power supply based on the control signal.

### CROSS-REFERENCE TO RELATED APPLICATION

This application is based upon and claims the benefit of priority of the prior Japanese Patent Application No. 2024-181531, filed on Oct. 17, 2024, the entire contents of which are incorporated herein by reference.

### BACKGROUND OF THE INVENTION

### 1. Field of the Invention

The embodiment discussed herein relates to a semiconductor device.

### 2. Background of the Related Art

In a semiconductor device in which a load is operated by switching of a power semiconductor element, an operation of switching between an operation state in which an internal power supply voltage is provided and a standby state in which the provision of the internal power supply voltage is stopped is performed.

As a related technique, for example, there has been proposed a technique including a first control device that controls only conduction and interruption of a power bipolar transistor and a second control device that detects an operation state of the power bipolar transistor and adjusts a value of a current flowing into a base terminal (Japanese Laid-open Patent Publication No. 09-051256). Further, a technique has been proposed in which a drive signal to be applied to a control terminal of a switching element is changed to a voltage or a current different from a predetermined voltage or a predetermined current according to a voltage value of the control terminal (International Publication Pamphlet No. 2008/155917).

### SUMMARY OF THE INVENTION

According to an aspect of the present disclosure, there is provided a semiconductor device including: an output element configured to be connected to a load and to operate the load; a clamp operation detection circuit configured to detect a clamp operation on the load and to output a clamp operation detection signal; an internal power supply instruction circuit configured to receive an input signal for performing switching driving of the output element, an abnormality detection signal indicating an abnormal device state of the semiconductor device, and the clamp operation detection signal, and to output a control signal instructing whether to provide an internal power supply based on the input signal, the abnormality detection signal and the clamp operation detection signal; and an internal power supply provision circuit configured to receive the control signal, and to control the provision of the internal power supply based on the control signal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram illustrating an example of a semiconductor device;

FIG. 2 is a diagram illustrating an example of the configuration of a semiconductor device;

FIG. 3 is a diagram illustrating an example of the configuration of a clamp operation detection circuit;

FIG. 4 is a diagram illustrating an example of the configuration of an internal power supply ON/OFF instruction circuit;

FIG. 5 is a diagram illustrating an example of the configuration of an internal power supply provision circuit;

FIG. 6 is a diagram illustrating an example of a time chart of provision control of an internal power supply voltage;

FIG. 7 is a diagram illustrating an example of a time chart of provision control of the internal power supply voltage;

FIG. 8 is a diagram illustrating an example of the configuration of a semiconductor device;

FIG. 9 is a diagram illustrating an example of the configuration of an internal power supply ON/OFF instruction circuit; and

FIG. 10 is a diagram illustrating an example of a time chart of provision control of an internal power supply voltage.

### DETAILED DESCRIPTION OF THE INVENTION

Hereinafter, an embodiment will be described with reference to the drawings. Note that, in this specification and the appended drawings, elements that have substantially the same structure are denoted with the same reference numerals, and repeated explanation of these elements may be omitted.

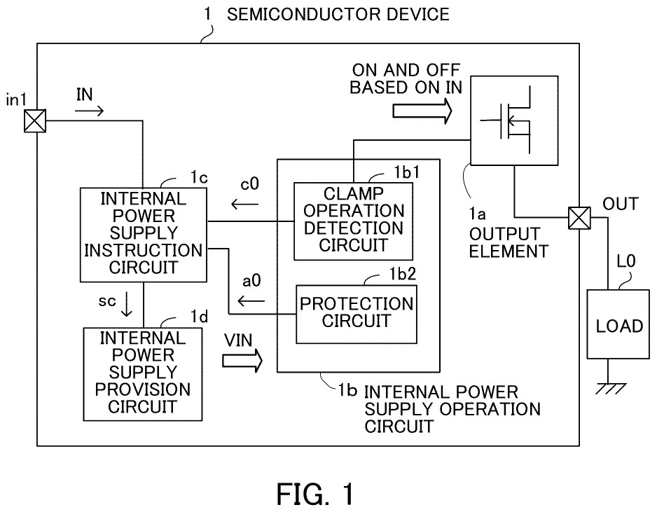

FIG. 1 is a diagram illustrating an example of a semiconductor device. This semiconductor device 1 includes an output element 1a, an internal power supply operation circuit 1b, an internal power supply instruction circuit 1c, and an internal power supply provision circuit 1d. The semiconductor device 1 is applicable to, for example, an intelligent power switch (IPS) in an automobile electrical system.

The internal power supply operation circuit 1b includes a clamp operation detection circuit 1b1 and a protection circuit 1b2. The internal power supply operation circuit 1b operates based on an internal power supply VIN provided from the internal power supply provision circuit 1d (in the following description, the internal power supply may be referred to as an internal power supply voltage).

The semiconductor device 1 includes an input terminal in1 and an output terminal OUT. An input signal IN transmitted from an external control unit (not illustrated) is input via the input terminal in1. The input signal IN is a signal for performing switching driving of the output element 1a. The control unit is, for example, an electronic control unit (ECU) mounted in an automobile. A load L0 is connected to the output terminal OUT. The load L0 is, for example, an inductive load such as a solenoid valve widely used in automobiles.

The output element 1a is a voltage-driven power semiconductor element, and is, for example, a power metal-oxide-semiconductor field-effect transistor (MOSFET). Alternatively, an insulated gate bipolar transistor (IGBT) may be used instead of the power MOSFET. The output element 1a performs the switching driving based on the input signal IN, to operate the load L0.

The clamp operation detection circuit 1b1 detects a clamp operation on the load L0 and outputs a clamp operation detection signal c0. The protection circuit 1b2 outputs an abnormality detection signal a0 when an abnormal device state is detected. The abnormal device state includes a low power supply voltage state in which the power supply voltage provided to the semiconductor device 1 decreases, an overcurrent state and an overheat state of the output element 1a, and the like. The protection circuit 1b2 outputs the abnormality detection signal a0 when at least one of these abnormal device states is detected.

Based on the input signal IN, the abnormality detection signal a0, and the clamp operation detection signal c0, the internal power supply instruction circuit 1c outputs a control signal sc instructing whether to provide the internal power supply voltage VIN. That is, the internal power supply instruction circuit 1c outputs a control signal sc instructing supply (supply ON) or stop of supply (supply OFF) of the internal power supply voltage VIN. The internal power supply provision circuit 1d controls the provision of the internal power supply voltage VIN to the internal power supply operation circuit 1b, based on the control signal sc.

As described above, in the semiconductor device 1, the provision of the internal power supply voltage is controlled based on various parameters indicating the device operation state, and examples of the parameters include the input signal, the abnormality detection signal, and the clamp operation detection signal. In this way, it is possible to accurately switch the supply and the stop of the provision of the internal power supply voltage to the internal power supply operation circuit operating with the internal power supply voltage. Therefore, it is possible to control the operation between the operation state in which the internal power supply voltage is provided and the standby state in which the provision of the internal power supply voltage is stopped, and it is possible to reduce the current consumption.

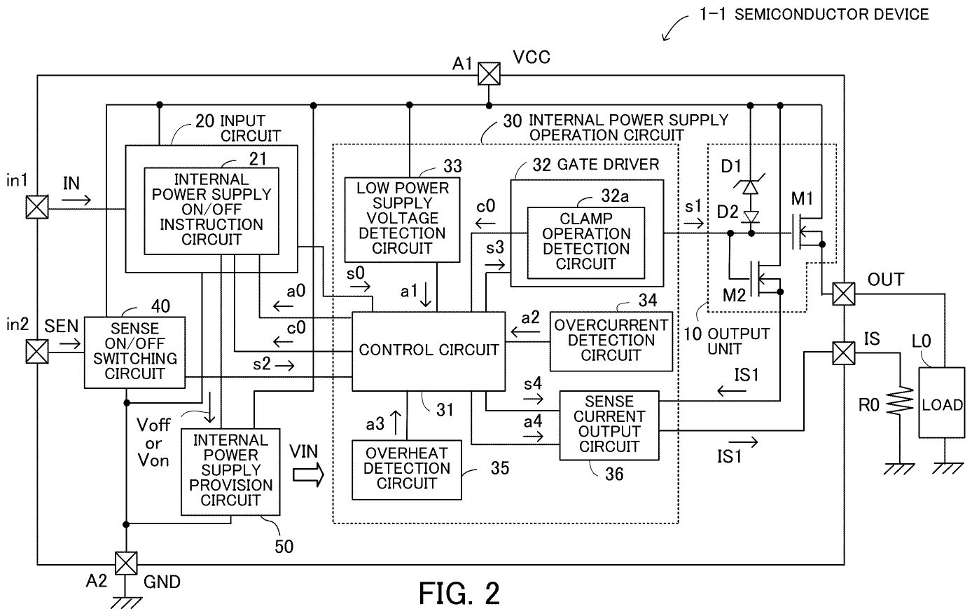

Next, the configuration and operation of the semiconductor device 1 will be described in detail below. FIG. 2 is a diagram illustrating an example of the configuration of a semiconductor device. This semiconductor device 1-1 includes a power supply terminal A1 to which a power supply voltage VCC is applied, and a ground terminal A2 connected to GND. In addition, the semiconductor device 1-1 includes, as external terminals, input terminals in1 and in2, an output terminal OUT, and a sense current output terminal IS.

An input signal IN transmitted from a control unit is input via the input terminal in1, and a sense current output instruction signal SEN transmitted from the control unit is input via the input terminal in2. One end of a load (inductive load) L0 is connected to the output terminal OUT, and the other end of the load L0 is connected to GND. One end of a resistor R0 is connected to the sense current output terminal IS, and the other end of the resistor R0 is connected to GND.

The semiconductor device 1-1 further includes an output unit 10, an input circuit 20, an internal power supply operation circuit 30, a sense ON/OFF switching circuit 40, and an internal power supply provision circuit 50. The internal power supply operation circuit 30 corresponds to the internal power supply operation circuit 1b in FIG. 1, and the internal power supply provision circuit 50 corresponds to the internal power supply provision circuit 1d in FIG. 1.

The output unit 10 includes an output element M1, a current monitoring element M2, and diodes D1 and D2. The diode D1 is a Zener diode. The input circuit 20 includes an internal power supply ON/OFF instruction circuit 21. The output element M1 corresponds to the output element 1a in FIG. 1, and the internal power supply ON/OFF instruction circuit 21 corresponds to the internal power supply instruction circuit 1c in FIG. 1.

The internal power supply operation circuit 30 includes a control circuit 31, a gate driver 32, a low power supply voltage detection circuit 33, an overcurrent detection circuit 34, an overheat detection circuit 35, and a sense current output circuit 36. The gate driver 32 includes a clamp operation detection circuit 32a.

The clamp operation detection circuit 32a corresponds to the clamp operation detection circuit 1b1 in FIG. 1. The control circuit 31, the low power supply voltage detection circuit 33, the overcurrent detection circuit 34, and the overheat detection circuit 35 implement the function of the protection circuit 1b2 illustrated in FIG. 1. These components included in the internal power supply operation circuit 30 operate based on an internal power supply voltage VIN provided from the internal power supply provision circuit 50.

The power supply voltage VCC is applied to the power supply terminals of the input circuit 20, the sense ON/OFF switching circuit 40, and the internal power supply provision circuit 50 via the power supply terminal A1. The ground terminals of the input circuit 20, the sense ON/OFF switching circuit 40, and the internal power supply provision circuit 50 are connected to GND via the ground terminal A2.

The output element M1 and the current monitoring element M2 are power MOSFETs. The output element M1 is turned on or off based on a drive signal s1 output from the gate driver 32, and operates the load L0. The current monitoring element M2 is an element that monitors the current flowing through the output element M1. When the drive signal s1 instructs to turn on the output element M1, the current monitoring element M2 causes a sense current Is1 proportional to the amount of current flowing through the output element M1 to flow to the sense current output circuit 36.

The diodes D1 and D2 for performing a clamp operation when a high voltage is generated are disposed between the drain and the gate of the output element M1. The diode D1 functions as a clamp diode that protects the output element M1 from an overvoltage generated by the inductance of the load L0 when the output element M1 is turned off, and the diode D2 functions as a backflow prevention diode.

The connection relationship of the components in the output unit 10 will be described. The drain of the output element M1 is connected to the power supply terminal A1, the drain of the current monitoring element M2, and the cathode of the diode D1. The power supply voltage VCC is applied to the drain of the output element M1. The anode of the diode D1 is connected to the anode of the diode D2. The gate of the output element M1 is connected to the cathode of the diode D2, the gate of the current monitoring element M2, and the gate driver 32. The source of the output element M1 is connected to the output terminal OUT. The source of the current monitoring element M2 is connected to a first input terminal of the sense current output circuit 36.

When the input circuit 20 receives the input signal IN through the input terminal in1, the input circuit 20 generates a logic signal s0 for turning on or off the output element M1, and outputs the logic signal s0 to the control circuit 31. The control circuit 31 outputs a drive control signal s3 for controlling turn-on or turn-off of the output element M1 to the gate driver 32, based on the logic signal s0 output from the input circuit 20, a low power supply voltage abnormality detection signal a1 from the low power supply voltage detection circuit 33, an overcurrent abnormality detection signal a2 from the overcurrent detection circuit 34, and an overheat abnormality detection signal a3 from the overheat detection circuit 35. The gate driver 32 generates the drive signal s1 having a level needed to turn on or off the output element M1, and applies the drive signal s1 to the gate of the output element M1 (the drive signal s1 is also applied to the gate of the current monitoring element M2).

The low power supply voltage detection circuit 33 determines whether the power supply voltage VCC applied to the power supply terminal A1 is in a low power supply voltage state. Upon detecting the low power supply voltage state, the low power supply voltage detection circuit 33 generates the low power supply voltage abnormality detection signal a1 indicating that the power supply voltage VCC is low, and transmits the low power supply voltage abnormality detection signal a1 to the control circuit 31.

The overcurrent detection circuit 34 determines whether the output element M1 is in an overcurrent state. Upon detecting the overcurrent state, the overcurrent detection circuit 34 generates the overcurrent abnormality detection signal a2 indicating that the output element M1 is in the overcurrent state, and transmits the overcurrent abnormality detection signal a2 to the control circuit 31.

The overheat detection circuit 35 determines whether the output element M1 is in an overheated state. Upon detecting the overheated state, the overheat detection circuit 35 generates the overheat abnormality detection signal a3 indicating that the output element M1 is in the overheated state, and transmits the overheat abnormality detection signal a3 to the control circuit 31.

Upon receiving the sense current output instruction signal SEN through the input terminal in2, the sense ON/OFF switching circuit 40 transmits a first output instruction signal s2 to the control circuit 31 such that the sense current Is1 monitored by the current monitoring element M2 is output from the sense current output terminal IS. Upon receiving the first output instruction signal s2, the control circuit 31 generates a second output instruction signal s4 for outputting the sense current, and outputs the second output instruction signal s4 to the sense current output circuit 36. Upon receiving the second output instruction signal s4 with a second input terminal, the sense current output circuit 36 outputs the sense current Is1 (or a sense current proportional to the amount of the sense current Is1) from the sense current output terminal IS.

1 When the control circuit 31 receives at least one of the low power supply voltage abnormality detection signal a1, the overcurrent abnormality detection signal a2, and the overheat abnormality detection signal a3 (when at least one abnormality is detected), the control circuit 31 transmits the drive control signal s3 instructing the gate driver 32 to stop the driving of the output element M1 to the gate driver 32. When the gate driver 32 receives the drive control signal s3 instructing the stop of the driving, the gate driver 32 turns off the output element M1 to stop the driving of the output element M1.

When the control circuit 31 does not receive any of the low power supply voltage abnormality detection signal a1, the overcurrent abnormality detection signal a2, and the overheat abnormality detection signal a3 (when none of the abnormalities is detected), the control circuit 31 transmits a drive control signal s3 instructing the gate driver 32 to drive the output element M1 to the gate driver 32. Upon receiving the drive control signal s3 instructing the driving, the gate driver 32 turns on the output element M1 to drive the output element M1.

Upon receiving at least one of the low power supply voltage abnormality detection signal a1, the overcurrent abnormality detection signal a2, and the overheat abnormality detection signal a3, the control circuit 31 generates an abnormality detection signal a0 and transmits the abnormality detection signal a0 to the internal power supply ON/OFF instruction circuit 21 included in the input circuit 20.

Further, upon receiving at least one of the overcurrent abnormality detection signal a2 and the overheat abnormality detection signal a3, the control circuit 31 generates an abnormality detection signal a4 and transmits the abnormality detection signal a4 to the sense current output circuit 36. Upon receiving the abnormality detection signal a4, the sense current output circuit 36 outputs an abnormality signal via the sense current output terminal IS in order to make a notification about the abnormal state of the output element M1.

On the other hand, the clamp operation detection circuit 32a included in the gate driver 32 detects a clamp operation on the load L0, generates a clamp operation detection signal c0 during the clamp operation, and transmits the clamp operation detection signal c0 to the control circuit 31. Upon receiving the clamp operation detection signal c0, the control circuit 31 relays and transmits the clamp operation detection signal c0 to the internal power supply ON/OFF instruction circuit 21.

When all of the input signal IN, the abnormality detection signal a0, and the clamp operation detection signal c0 are in an invalid state, the internal power supply ON/OFF instruction circuit 21 outputs an internal power supply OFF signal Voff that turns off the provision of the internal power supply voltage VIN and causes the internal power supply operation circuit 30 to transition to a standby state.

When at least one of the input signal IN, the abnormality detection signal a0, and the clamp operation detection signal c0 is in a valid state, the internal power supply ON/OFF instruction circuit 21 outputs an internal power supply ON signal Von that turns on the provision of the internal power supply voltage VIN and causes the internal power supply operation circuit 30 to transition to an operation state.

The internal power supply OFF signal Voff and the internal power supply ON signal Von correspond to the control signal sc illustrated in FIG. 1. When the input signal IN is at an L level, the internal power supply ON/OFF instruction circuit 21 determines that the input signal IN is invalid. Similarly, when the abnormality detection signal a0 is at an L level, the internal power supply ON/OFF instruction circuit 21 determines that the abnormality detection signal a0 is invalid. In addition, when the clamp operation detection signal c0 is at an L level, the internal power supply ON/OFF instruction circuit 21 determines that the clamp operation detection signal c0 is invalid.

When the input signal IN is at an H level, the internal power supply ON/OFF instruction circuit 21 determines that the input signal IN is valid. Similarly, when the abnormality detection signal a0 is at an H level, the internal power supply ON/OFF instruction circuit 21 determines that the abnormality detection signal a0 is valid. In addition, when the clamp operation detection signal c0 is at an H level, the internal power supply ON/OFF instruction circuit 21 determines that the clamp operation detection signal c0 is valid.

Upon receiving the internal power supply OFF signal Voff, the internal power supply provision circuit 50 stops the provision of the internal power supply voltage VIN to the internal power supply operation circuit 30, and sets the internal power supply operation circuit 30 to the standby state. Upon receiving the internal power supply ON signal Von, the internal power supply provision circuit 50 provides the internal power supply voltage VIN to the internal power supply operation circuit 30, and sets the internal power supply operation circuit 30 to the operation state.

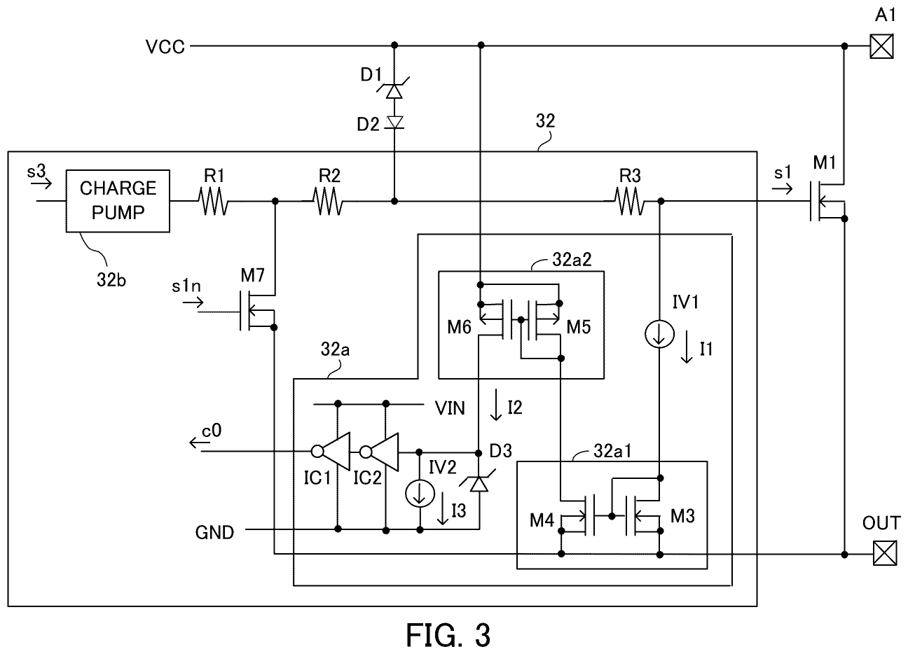

FIG. 3 is a diagram illustrating an example of the configuration of the clamp operation detection circuit. The clamp operation detection circuit 32a included in the gate driver 32 is a circuit that monitors the gate voltage of the output element M1 and outputs the clamp operation detection signal c0. The clamp operation detection circuit 32a includes a current mirror circuit 32a1 (a first current mirror circuit), a current mirror circuit 32 a2 (a second current mirror circuit), a constant current source IV1 (a first constant current source), a constant current source IV2 (a second constant current source), an inverter element IC1 (a first inverter element), an inverter element IC2 (a second inverter element), and a diode D3 (a first diode). The diode D3 is a Zener diode.

The current mirror circuit 32a1 includes a MOS transistor M3 (a first MOS transistor) and a MOS transistor M4 (a second MOS transistor). The current mirror circuit 32 a2 includes a MOS transistor M5 (a third MOS transistor) and a MOS transistor M6 (a fourth MOS transistor). NMOS transistors are used as the MOS transistors M3 and M4, and PMOS transistors are used as the MOS transistors M5 and M6.

Resistors R1, R2, and R3 (gate resistors) around the clamp operation detection circuit 32a, a MOS transistor M7, and a charge pump 32b are included in the gate driver 32. An NMOS transistor is used as the MOS transistor M7.

The connection relationship of these components will be described. The input terminal of the constant current source IV1 is connected to the gate of the output element M1 and one end of the resistor R3. The output terminal of the constant current source IV1 is connected to the drain of the MOS transistor M3, the gate of the MOS transistor M3, and the gate of the MOS transistor M4.

The source of the MOS transistor M3 is connected to the back gate of the MOS transistor M3, the source of the MOS transistor M4, the back gate of the MOS transistor M4, the source of the output element M1, and the output terminal OUT. Further, the source of the MOS transistor M3 is connected to the source of the MOS transistor M7 and the back gate of the MOS transistor M7.

The source of the MOS transistor M5 is connected to the back gate of the MOS transistor M5, the source of the MOS transistor M6, the back gate of the MOS transistor M6, and the power supply terminal A1. The power supply voltage VCC is applied to the source of the MOS transistor M5. The source of the MOS transistor M5 is also connected to the cathode of the diode D1.

The gate of the MOS transistor M5 is connected to the gate of the MOS transistor M6, the drain of the MOS transistor M5, and the drain of the MOS transistor M4. The drain of the MOS transistor M6 is connected to the cathode of the diode D3, the input terminal of the constant current source IV2, and the input terminal of the inverter element IC2. The anode of the diode D3 and the output terminal of the constant current source IV2 are connected to GND.

The output terminal of the inverter element IC2 is connected to the input terminal of the inverter element IC1. A clamp operation detection signal c0 is output from the output terminal of the inverter element IC1. The internal power supply voltage VIN is applied to the power supply terminals of the inverter elements IC1 and IC2, and the ground terminals are connected to GND.

The other end of the resistor R3 is connected to the cathode of the diode D2 and one end of the resistor R2. The other end of the resistor R2 is connected to the drain of the MOS transistor M7 and one end of the resistor R1. The other end of the resistor R1 is connected to the output end of the charge pump 32b.

Based on the drive control signal s3 output from the control circuit 31, the charge pump 32b generates the drive signal s1 by boosting the drive control signal s3 to a level needed to turn on the output element M1, and inputs the drive signal s1 to the gate of the output element M1 via the resistors R1, R2, and R3.

The MOS transistor M7 has a gate charge extraction function of extracting the charge of the gate of the output element M1. When the output element M1 is turned on, an L-level signal s1n generated in the gate driver 32 is input to the gate of the MOS transistor M7, and the MOS transistor M7 is consequently turned off. When the output element M1 is turned off, an H-level signal s1n generated in the gate driver 32 is input to the gate of the MOS transistor M7. As a result, the MOS transistor M7 is turned on, and the charge is extracted from the gate of the output element M1.

When the output element M1 is turned off, a clamp operation for absorbing the coil energy of the load L0 is performed. At this time, in order to release the coil energy, the gate voltage of the output element M1 becomes a voltage needed for absorbing the coil energy. The clamp operation detection circuit 32a monitors this voltage (the gate voltage of the output element M1) to detect that the coil energy absorption operation is in progress.

The clamp operation detection circuit 32a outputs an H-level clamp operation detection signal c0 during the clamp operation (during the operation of absorbing coil energy), and outputs an L-level clamp operation detection signal c0 when the clamp operation is completed (when the operation of absorbing coil energy is completed).

A current I1 output from the constant current source IV1 is a small current of a level that does not affect the gate voltage of the output element M1 (a current smaller than the current of the drive signal s1). The threshold values of the MOS transistors M3 and M4 are set to be lower than the threshold value of the output element M1 so that the MOS transistors M3 and M4 may be turned on even during the clamp operation.

On the other hand, when the coil energy of the load L0 decreases during the clamp operation, the gate voltage of the output element M1 decreases. At this time, since the gate voltage of the MOS transistor M3 decreases, the current I1 decreases, and a current I2 output from the current mirror circuit 32 a2 decreases. If the current I2 is not larger than a current I3 output from the constant current source IV2, the circuit operation becomes unstable. Therefore, in order to reliably set the current I2 to a larger current value than the current I3, it is desirable that the MOS transistor M6 be configured such that a larger current flows from the MOS transistor M6 than the current that flows from the MOS transistor M5.

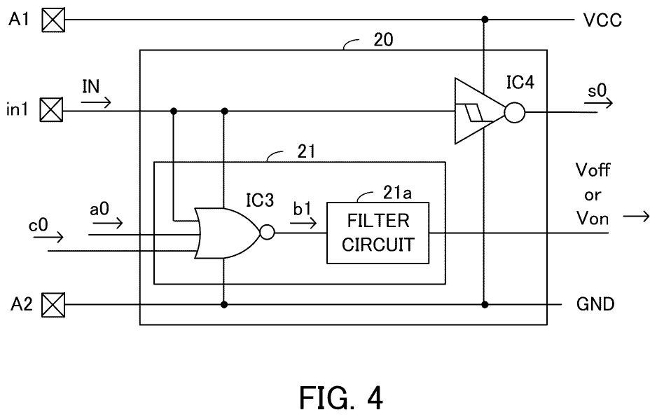

FIG. 4 is a diagram illustrating an example of the configuration of the internal power supply ON/OFF instruction circuit. The input circuit 20 includes an internal power supply ON/OFF instruction circuit 21 and an inverter element IC4. The internal power supply ON/OFF instruction circuit 21 includes a 3-input 1-output NOR element IC3 and a filter circuit 21a. The inverter element IC4 is a Schmitt trigger inverter element.

The input signal IN is input to the input terminal of the inverter element IC4, and the logic signal s0 is output from the output terminal of the inverter element IC4. The input signal IN is input to a first input terminal of the NOR element IC3, the abnormality detection signal a0 is input to a second input terminal, and the clamp operation detection signal c0 is input to a third input terminal. The output terminal of the NOR element IC3 is connected to the input terminal of the filter circuit 21a.

The filter circuit 21a performs a filtering process on a signal b1 output from the NOR element IC3 and outputs the signal b1 as the internal power supply ON signal Von or the internal power supply OFF signal Voff after a predetermined time.

When all of the input signal IN, the abnormality detection signal a0, and the clamp operation detection signal are at an L level, the NOR element IC3 outputs an H-level signal b1, and an H-level internal power supply OFF signal Voff (a first-level control signal) is output via the filter circuit 21a.

That is, when the input signal IN is at an L level, the turn-off of the output element M1 is instructed. When the abnormality detection signal a0 is at an L level, there is no abnormality (a low power supply voltage, overcurrent, overheat) in the device. In addition, when the clamp operation detection signal c0 is at an L level, the clamp operation has already been completed.

As described above, when all of the input signal, the abnormality detection signal, and the clamp operation detection signal are at an L level, the internal power supply ON/OFF instruction circuit 21 outputs the internal power supply OFF signal Voff (H level) for turning off the provision of the internal power supply voltage VIN after a predetermined time and causing the internal power supply operation circuit 30 to transition to the standby state.

When at least one of the input signal IN, the abnormality detection signal a0, and the clamp operation detection signal is at an H level, the NOR element IC3 outputs an L-level signal b1, and an L-level internal power supply ON signal Von (a second-level control signal) is output via the filter circuit 21a.

That is, when the input signal IN is at an H level, the turn-on of the output element M1 is instructed. When the abnormality detection signal a0 is at an H level, there is an abnormality (at least one of a low power supply voltage, overcurrent, and overheat) in the device. In addition, when the clamp operation detection signal c0 is at an H level, the clamp operation has not been completed yet.

As described above, when at least one of the input signal, the abnormality detection signal, and the clamp operation detection signal is in a valid state, the internal power supply ON/OFF instruction circuit 21 outputs the internal power supply ON signal Von (L level) for turning on the provision of the internal power supply voltage VIN and causing the internal power supply operation circuit 30 to transition to the operation state.

The operation threshold level of the NOR element IC3 is set lower than the operation threshold level of the inverter element IC4. Thus, the gate driver 32 in the internal power supply operation circuit 30 is able to reliably receive the drive control signal s3 in a state where the internal power supply operation circuit 30 is operated by the internal power supply ON signal Von.

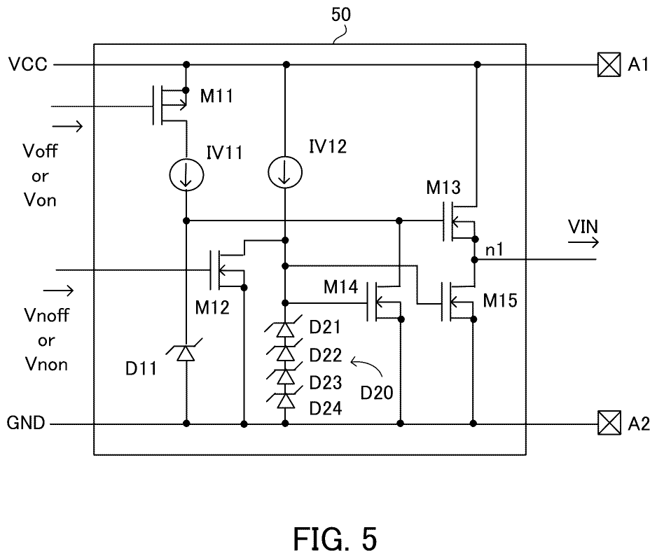

FIG. 5 is a diagram illustrating an example of the configuration of the internal power supply provision circuit. The internal power supply provision circuit 50 includes a MOS transistor M11 (a fifth MOS transistor), a MOS transistor M12 (a sixth MOS transistor), a MOS transistor M13 (a seventh MOS transistor), a MOS transistor M14 (an eighth MOS transistor), a MOS transistor M15 (a ninth MOS transistor), a constant current source IV11 (a third constant current source), a constant current source IV12 (a fourth constant current source), a diode D11 (a second diode), and a diode group D20.

MOS transistor M11 is a PMOS transistor, and the MOS transistors M12, M13, M14, and M15 are NMOS transistors. The diode group D20 includes a plurality of diodes D21, D22, D23, and D24 (a plurality of third diodes). The diodes D11, D21, D22, D23, and D24 are Zener diodes.

The connection relationship of these components will be described. The source of the MOS transistor M11 is connected to the back gate of the MOS transistor M11, the input terminal of the constant current source IV12, the drain of the MOS transistor M13, and the power supply terminal A1. The power supply voltage VCC is applied to the source of the MOS transistor M11.

The drain of the MOS transistor M11 is connected to the input terminal of the constant current source IV11. The output terminal of the constant current source IV11 is connected to the cathode of the diode D11, the gate of the MOS transistor M13, and the drain of the MOS transistor M14.

The output terminal of the constant current source IV12 is connected to the drain of the MOS transistor M12, the gate of the MOS transistor M14, the gate of the MOS transistor M15, and the cathode of the diode D21 (the cathode of the diode group).

The anode of the diode D21 is connected to the cathode of the diode D22, the anode of the diode D22 is connected to the cathode of the diode D23, and the anode of the diode D23 is connected to the cathode of the diode D24.

The anode of the diode D11 is connected to the ground terminal A2 and is connected to GND. The anode of the diode D11 is connected to the source of the MOS transistor M12, the back gate of the MOS transistor M12, the anode of the diode D24 (the anode of the diode group), the source of the MOS transistor M14, the back gate of the MOS transistor M14, the source of the MOS transistor M15, and the back gate of the MOS transistor M15.

A control signal is input to the gates of the MOS transistors M11 and M12. When the internal power supply OFF signal Voff is input to the gate of the MOS transistor M11, an inverted level signal Vnoff of the internal power supply OFF signal Voff is input to the gate of the MOS transistor M12. When the internal power supply ON signal Von is input to the gate of the MOS transistor M11, an inverted level signal Vnon of the internal power supply ON signal Von is input to the gate of the MOS transistor M12. The internal power supply voltage VIN is output from a connection node n1 between the source of the MOS transistor M13 and the drain of the MOS transistor M15.

The inverted level signal Vnoff and the inverted level signal Vnon may be generated by inverting the internal power supply OFF signal Voff and the internal power supply ON signal Von by an inverter element.

### Operation When Supply of Internal Power Supply Voltage VIN is On

Since an L-level internal power supply ON signal Von is input to the gate of the MOS transistor M11, the MOS transistor M11 is turned on. When the MOS transistor M11 is turned on, a current from the constant current source IV11 flows through the diode D11, and a voltage generated thereby is input to the gate of the MOS transistor M13.

In addition, the MOS transistor M12 is turned on by the inverted level signal Vnon (H level) of the internal power supply ON signal Von. At this time, since the MOS transistors M14 and M15 are turned off, the gate and the source of the MOS transistor M13 are not short-circuited to GND, the provision of the internal power supply voltage VIN is turned on, and the internal power supply voltage VIN is output from the connection node n1.

### Operation When Supply of Internal Power Supply Voltage VIN is Off

Since an H-level internal power supply OFF signal Voff is input to the gate of the MOS transistor M11, the MOS transistor M11 is turned off. Since the MOS transistor M11 is turned off, the provision of the charge to the gate of the MOS transistor M13 is stopped.

0 In addition, the MOS transistor M12 is turned off by the inverted level signal Vnoff (L level) of the internal power supply OFF signal Voff. At this time, since the MOS transistors M14 and M15 are turned on, the gate and the source of the MOS transistor M13 are short-circuited to GND, the connection node n1 reaches the GND voltage, the provision of the internal power supply voltage VIN is turned off, and the output of the internal power supply voltage VIN is stopped. When the MOS transistors M11 and M12 are off and the power supply voltage VCC is equal to or less than a reverse breakdown voltage VZ of the diode group D20, no current flows.

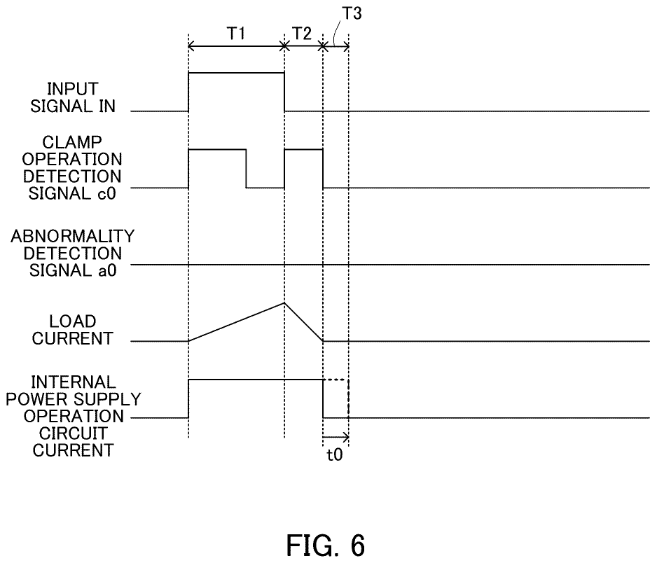

FIG. 6 is a diagram illustrating an example of a time chart of provision control of the internal power supply voltage. FIG. 6 illustrates a state in which there is no abnormal state (a low power supply voltage, overcurrent, overheat) in the device.

[Period T1] An H-level input signal IN instructing turn-on of the output element M1 is input. Since the clamp operation detection circuit 32a monitors the gate voltage of the output element M1, there is a time period in which the clamp operation detection circuit 32a outputs an H-level clamp operation detection signal c0 even in the normal operation after the turn-on of the output element M1. Because there is no abnormality, the abnormality detection signal a0 is at an L level. Since the output element M1 is turned on, the load current flowing through the output element M1 and the load L0 increases.

Since the input signal IN and the clamp operation detection signal c0 are at an H level, the internal power supply ON/OFF instruction circuit 21 outputs the internal power supply ON signal Von. The internal power supply provision circuit 50 provides the internal power supply voltage VIN to the internal power supply operation circuit 30 based on the internal power supply ON signal Von. Therefore, a current (hereinafter sometimes referred to as an internal power supply operation circuit current) flows through the internal power supply operation circuit 30.

[Period T2] An L-level input signal IN instructing turn-off of the output element M1 is input. The clamp operation detection circuit 32a outputs an H-level clamp operation detection signal c0 during the clamp operation. Because there is no abnormality, the abnormality detection signal a0 is at an L level. Since the output element M1 starts turning off, the load current decreases.

Since the clamp operation detection signal c0 is at an H level, the internal power supply ON/OFF instruction circuit 21 outputs the internal power supply ON signal Von. The internal power supply provision circuit 50 provides the internal power supply voltage VIN to the internal power supply operation circuit 30 based on the internal power supply ON signal Von. Therefore, an internal power supply operation circuit current flows through the internal power supply operation circuit 30.

[Period T3] The L-level input signal IN is continuously input. The clamp operation detection circuit 32a completes the clamp operation and outputs an L-level clamp operation detection signal c0. Because there is no abnormality, the abnormality detection signal a0 is at the L level. Since the output element M1 is turned off, the load current does not flow.

Here, in the internal power supply ON/OFF instruction circuit 21, the filter circuit 21a detects that all the input signal IN, the abnormality detection signal a0, and the clamp operation detection signal c0 are at the L level by the filtering processing (output delay setting processing) and outputs the internal power supply OFF signal Voff after the elapse of a predetermined time t0.

Therefore, even when all of the input signal IN, the abnormality detection signal a0, and the clamp operation detection signal c0 are at the L level, the internal power supply ON/OFF instruction circuit 21 outputs the internal power supply ON signal Von until the predetermined time t0 elapses. The internal power supply ON/OFF instruction circuit 21 outputs the internal power supply OFF signal Voff after the predetermined time t0 is reached.

In this way, even when ringing occurs in the input signal IN, the abnormality detection signal a0, and the clamp operation detection signal c0, it is possible to prevent the internal power supply operation circuit 30 from erroneously transitioning to the standby state due to the occurrence of the ringing. After the period T3 (after the predetermined time t0), since the internal power supply ON/OFF instruction circuit 21 outputs the internal power supply OFF signal Voff, the internal power supply provision circuit 50 stops the provision of the internal power supply voltage VIN. Therefore, the internal power supply operation circuit current does not flow.

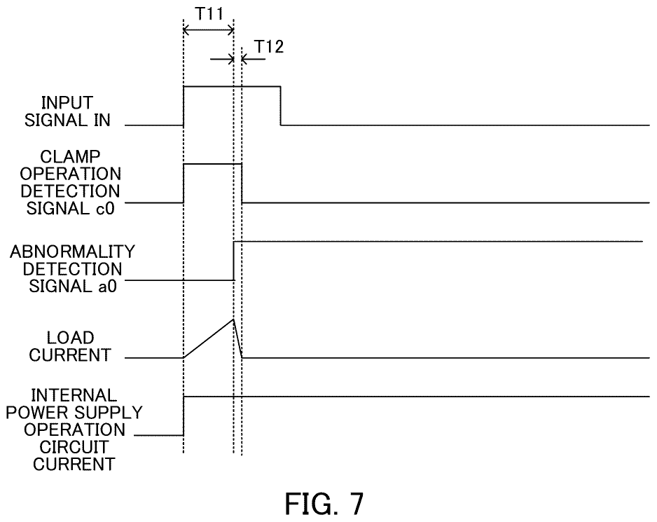

FIG. 7 is a diagram illustrating an example of a time chart of provision control of the internal power supply voltage. FIG. 7 illustrates a state in which an abnormal device state (at least one of a low power supply voltage, overcurrent, and overheat) has occurred in the device during operation.

[Period T11] An H-level input signal IN instructing turn-on of the output element M1 is input. Since the clamp operation detection circuit 32a monitors the gate voltage of the output element M1, there is a time period in which the clamp operation detection circuit 32a outputs an H-level clamp operation detection signal c0 even in the normal operation after the turn-on of the output element M1. Because there is no abnormality, the abnormality detection signal a0 is at an L level. Since the output element M1 is turned on, the load current flowing through the output element M1 and the load L0 increases.

Since the input signal IN and the clamp operation detection signal c0 are at an H level, the internal power supply ON/OFF instruction circuit 21 outputs the internal power supply ON signal Von. The internal power supply provision circuit 50 provides the internal power supply voltage VIN to the internal power supply operation circuit 30 based on the internal power supply ON signal Von. Therefore, an internal power supply operation circuit current flows through the internal power supply operation circuit 30.

[Period T12] An H-level input signal IN is continuously input. Since the clamp operation detection circuit 32a monitors the gate voltage of the output element M1, there is a time period in which the clamp operation detection circuit 32a outputs an H-level clamp operation detection signal c0 even in the normal operation after the turn-on of the output element M1. In addition, since an abnormal state has occurred, the abnormality detection signal a0 rises to an H level. When the control circuit 31 detects at least one of the low power supply voltage abnormality detection signal a1, the overcurrent abnormality detection signal a2, and the overheat abnormality detection signal a3, the control circuit 31 outputs a drive control signal s3 instructing to stop the driving of the output element M1 to the gate driver 32. Upon receiving the drive control signal s3 instructing to stop the driving, the gate driver 32 turns off the output element M1 to interrupt the current. As a result, the load current decreases.

Since at least one of the input signal IN, the clamp operation detection signal c0, and the abnormality detection signal a0 is at an H level, the internal power supply ON/OFF instruction circuit 21 outputs the internal power supply ON signal Von. The internal power supply provision circuit 50 provides the internal power supply voltage VIN to the internal power supply operation circuit 30 based on the internal power supply ON signal Von.

Therefore, the internal power supply operation circuit current flows through the internal power supply operation circuit 30. After the period T12, the input signal IN becomes an L level after a predetermined time has elapsed, and the clamp operation detection signal c0 is at an L level. However, the abnormality detection signal a0 is continuously output at an H level. Therefore, the internal power supply ON/OFF instruction circuit 21 outputs the internal power supply ON signal Von, and the internal power supply provision circuit 50 continues to provide the internal power supply voltage VIN to the internal power supply operation circuit 30. Therefore, the internal power supply operation circuit current continues to flow through the internal power supply operation circuit 30.

As described above, the semiconductor device 1-1 is configured to control the provision of the internal power supply voltage based on the input signal, the abnormality detection signal, and the clamp operation detection signal. Thus, it is possible to accurately switch the provision of the internal power supply voltage to the internal power supply operation circuit operating with the internal power supply voltage and the stop of the provision of the internal power supply voltage. For example, it is possible to prevent the provision of the internal power supply voltage from being stopped during the clamp operation of the coil energy absorption. Further, since the state in which the provision of the internal power supply voltage may be stopped is accurately determined, the operation between the operation state in which the internal power supply voltage is provided and the standby state in which the provision of the internal power supply voltage is stopped is controlled, and the current consumption is reduced. For example, it is possible to reduce the current consumption by shortening the time needed for the transition from the operation state in which the internal power supply voltage is provided to the standby state in which the provision of the internal power supply voltage is stopped.

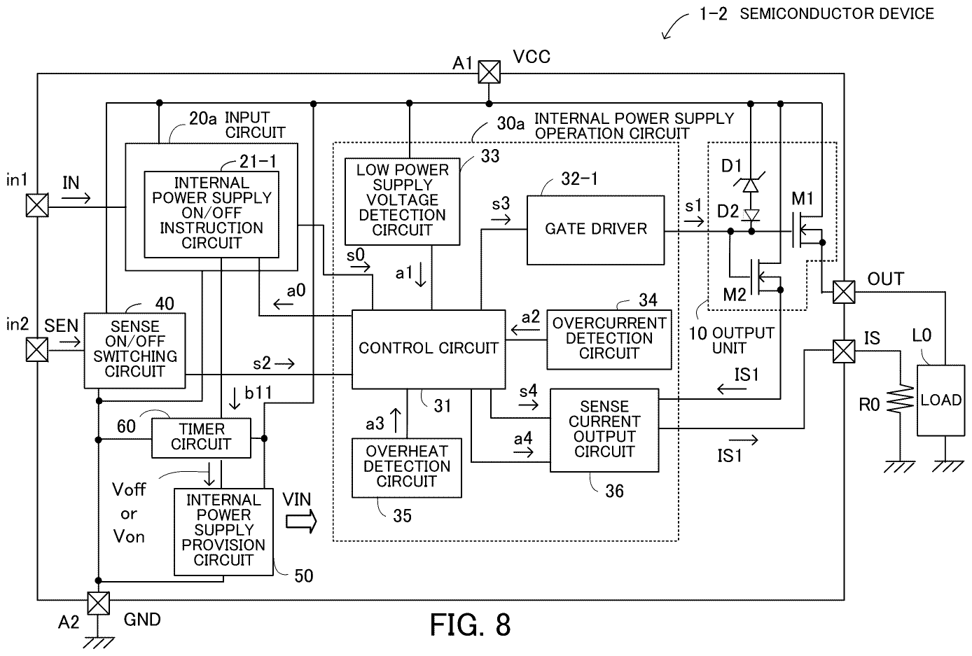

When the provision of the internal power supply voltage is controlled, a relay may be provided in the semiconductor device, and the provision of the internal power supply voltage may be turned on and off by switching the relay. However, in such a device, a mechanical relay, a fuse, or the like is mounted, which causes an increase in circuit scale. On the other hand, in the semiconductor device 1-1 of the present embodiment, such a device is not needed. Thus, since the circuit scale is reduced, highly accurate control of the provision of the internal power supply voltage is realized with a compact configuration. 108 Next, a modification of the semiconductor device will be described. FIG. 8 is a diagram illustrating an example of the configuration of a semiconductor device. The semiconductor device 1-2 of the modification includes an output unit 10, an input circuit 20a, an internal power supply operation circuit 30a, a sense ON/OFF switching circuit 40, an internal power supply provision circuit 50, and a timer circuit 60.

The difference from the semiconductor device 1-1 illustrated in FIG. 2 is that the input circuit 20a includes an internal power supply ON/OFF instruction circuit 21-1. A gate driver 32-1 does not include the clamp operation detection circuit 32a. Further, the timer circuit 60 is provided as an additional component. The other components are the same as those in FIG. 2.

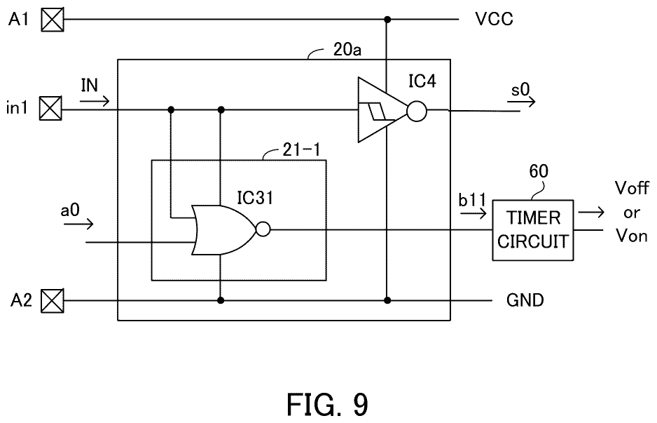

FIG. 9 is a diagram illustrating an example of the configuration of the internal power supply ON/OFF instruction circuit. The internal power supply ON/OFF instruction circuit 21-1 does not include the filter circuit 21a illustrated in FIG. 4, but includes a 2-input 1-output NOR element IC31. A signal b11 output from the NOR element IC31 is transmitted to the timer circuit 60.

Here, when both the input signal IN and the abnormality detection signal a0 are at an L level, the NOR element IC31 outputs an H-level signal b11. Upon receiving the H-level signal b11 (a first level control signal), the timer circuit 60 drives a timer to measure a predetermined time. The timer circuit 60 outputs the internal power supply OFF signal Voff, which is the H-level signal b11, after measuring the predetermined time.

That is, when the input signal IN is at an L level, the turn-off of the output element M1 is instructed. When the abnormality detection signal a0 is at an L level, there is no abnormality (a low power supply voltage, overcurrent, overheat) in the device.

As described above, when the input signal and the abnormality detection signal are in an invalid state, the timer circuit 60 receives the H-level signal b11 from the internal power supply ON/OFF instruction circuit 21-1, measures a predetermined time, and outputs the internal power supply OFF signal Voff for causing the internal power supply operation circuit 30a to transition to the standby state after the predetermined time has elapsed.

When at least one of the input signal IN and the abnormality detection signal a0 is at an H level, the NOR element IC31 outputs an L-level signal b11 (a second-level control signal). Upon receiving the L-level signal b11, the timer circuit 60 deactivates the timer and outputs the internal power supply ON signal Von, which is the L-level signal b11.

That is, when the input signal IN is at an H level, the turn-on of the output element M1 is instructed. When the abnormality detection signal a0 is at an H level, there is an abnormality (at least one of a low power supply voltage, overcurrent, and overheat) in the device.

As described above, when at least one of the input signal IN and the abnormality detection signal a0 is received, the timer circuit 60 receives an L-level signal b11 from the internal power supply ON/OFF instruction circuit 21-1, deactivates the timer, and outputs the internal power supply ON signal Von for causing the internal power supply operation circuit 30a to transition to the operation state.

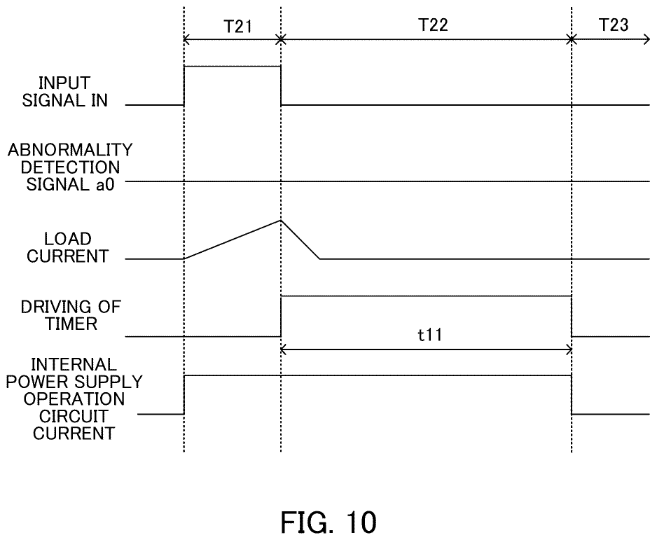

FIG. 10 is a diagram illustrating an example of a time chart of provision control of the internal power supply voltage. FIG. 10 illustrates a state in which there is no abnormality (a low power supply voltage, overcurrent, overheat) in the device.

[Period T21] An H-level input signal IN instructing turn-on of the output element M1 is input. Because there is no abnormality, the abnormality detection signal a0 is at an L level. Since the output element M1 is turned on, the load current flowing through the output element M1 and the load L0 increases.

Since the input signal IN is at an H level, the internal power supply ON/OFF instruction circuit 21-1 outputs an L-level signal b11. The timer circuit 60 deactivates the timer based on the L-level signal b11 and outputs the internal power supply ON signal Von. The internal power supply provision circuit 50 provides the internal power supply voltage VIN to the internal power supply operation circuit 30 based on the internal power supply ON signal Von. Therefore, an internal power supply operation circuit current flows through the internal power supply operation circuit 30.

[Period T22] An L-level input signal IN instructing turn-off of the output element M1 is input. Because there is no abnormality, the abnormality detection signal a0 is at an L level. Since the output element M1 starts turning off, the load current decreases. 121 Here, since both the input signal IN and the abnormality detection signal a0 are at an L level, the internal power supply ON/OFF instruction circuit 21-1 outputs an H-level signal b11. The timer circuit 60 drives a timer for measuring a predetermined time t11 based on the H-level signal b11. During driving of the timer, the internal power supply ON signal Von is output.

Therefore, even when both the input signal IN and the abnormality detection signal a0 are at an L level, the internal power supply ON signal Von is output until the predetermined time t11 elapses, and the internal power supply operation circuit current continues to flow during the predetermined time t11.

[Period T23] The L-level input signal IN is continuously input. Since there is no abnormality, the abnormality detection signal a0 is continuously at the L level. Since the output element M1 remains turned off, no load current flows.

Here, since both of the input signal IN and the abnormality detection signal a0 are at an L level, the internal power supply ON/OFF instruction circuit 21-1 outputs an H-level signal b11. When the timer driving of the timer circuit 60 ends and the measurement of the predetermined time t11 ends, the timer circuit 60 outputs the internal power supply OFF signal Voff. Since the internal power supply provision circuit 50 stops the provision of the internal power supply voltage VIN due to the internal power supply OFF signal Voff, the internal power supply operation circuit current does not flow.

As described above, in the semiconductor device 1-2, on/off of the provision of the internal power supply voltage is instructed based on the input signal IN and the abnormality detection signal a0, the timer circuit 60 drives the timer according to the instruction, and the provision of the internal power supply voltage is controlled based on the control signal output from the timer circuit 60. 126 With this configuration, even when the input signal IN and the abnormality detection signal a0 are in an invalid state, the provision of the internal power supply voltage is not immediately turned off. The provision of the internal power supply voltage is turned off after the elapse of a predetermined time by a delay setting of the timer circuit 60.

Therefore, it is possible to prevent malfunctions. For example, turning off the provision of the internal power supply voltage even though a state in which the provision of the internal power supply voltage is needed (for example, during the clamp operation) continues is prevented. In addition, since it is possible to set an arbitrary time in the timer circuit 60, it is possible to accurately control the time needed for the transition from the operation state in which the internal power supply voltage is provided to the standby state in which the provision of the internal power supply voltage is stopped. Thus, it is possible to reduce the current consumption.

According to one aspect, it is possible to reduce the current consumption by controlling the transition operation from the operation state to the standby state.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an output element configured to be connected to a load and to operate the load;
a clamp operation detection circuit configured to detect a clamp operation on the load and to output a clamp operation detection signal;
an internal power supply instruction circuit configured
to receive
an input signal for performing switching driving of the output element,
an abnormality detection signal indicating an abnormal device state of the semiconductor device, and
the clamp operation detection signal, and
to output a control signal instructing whether to provide an internal power supply based on the input signal, the abnormality detection signal and the clamp operation detection signal; and
an internal power supply provision circuit configured to receive the control signal, and to control the provision of the internal power supply based on the control signal.

2. The semiconductor device according to claim 1, further comprising an internal power supply operation circuit, wherein
the clamp operation detection circuit is included in the internal power supply operation circuit, and
the internal power supply operation circuit further includes a protection circuit that operates with the internal power supply and outputs the abnormality detection signal upon detecting the abnormal device state.

3. The semiconductor device according to claim 2, wherein the control signal outputted by the internal power supply instruction circuit is
of a first level to stop the provision of the internal power supply, when each of the input signal, the abnormality detection signal, and the clamp operation detection signal indicates an invalid state, and
of a second level to instruct the provision of the internal power supply, when at least one of the input signal, the abnormality detection signal, or the clamp operation detection signal indicates a valid state.

4. The semiconductor device according to claim 3,
wherein the internal power supply provision circuit stops, upon receiving the control signal of the first level, the provision of the internal power supply to the internal power supply operation circuit, to set the internal power supply operation circuit to a standby state, and
wherein the internal power supply provision circuit provides, upon receiving the control signal of the second level, the internal power supply to the internal power supply operation circuit, to set the internal power supply operation circuit to an operation state.

5. The semiconductor device according to claim 1,
wherein the clamp operation detection circuit includes:
a first current mirror circuit including a first metal-oxide-semiconductor (MOS) transistor and a second MOS transistor,
a second current mirror circuit including a third MOS transistor and a fourth MOS transistor,
a first constant current source,
a second constant current source,
a first diode,
a first inverter element, and
a second inverter element, and
wherein the internal power supply is provided to the first inverter element and the second inverter element.

6. The semiconductor device according to claim 5,
wherein each of the output element, the first MOS transistor, the second MOS transistor, the third MOS transistor and the fourth MOS transistor has a gate, a drain, a source and a back gate,
wherein each of the first constant current source and the second constant current source has an input terminal and an output terminal,
wherein the first diode has a cathode and an anode,
wherein each of the first inverter element and the second inverter element has an input terminal, an output terminal and a ground terminal,
wherein the input terminal of the first constant current source is connected to the gate of the output element, and the output terminal of the first constant current source is connected to the drain of the first MOS transistor, the gate of the first MOS transistor, and the gate of the second MOS transistor,
wherein the source of the first MOS transistor is connected to the back gate of the first MOS transistor, the source of the second MOS transistor, the back gate of the second MOS transistor, the source of the output element, and the back gate of the output element,
wherein the source of the third MOS transistor is connected to the back gate of the third MOS transistor, the source of the fourth MOS transistor, the back gate of the fourth MOS transistor, and a power supply terminal,
wherein the gate of the third MOS transistor is connected to the gate of the fourth MOS transistor, the drain of the third MOS transistor, and the drain of the second MOS transistor,
wherein the drain of the fourth MOS transistor is connected to the cathode of the first diode, the input terminal of the second constant current source, and the input terminal of the second inverter element,
wherein the anode of the first diode, the output terminal of the second constant current source, the ground terminal of the first inverter element, and the ground terminal of the second inverter element are grounded, and
wherein the output terminal of the second inverter element is connected to the input terminal of the first inverter element, and the clamp operation detection signal is output from the output terminal of the first inverter element.

7. The semiconductor device according to claim 1,
wherein the internal power supply instruction circuit includes:
an NOR element having a first input terminal, a second input terminal, a third input terminal and an output terminal, and
a filter circuit having an input terminal and an output terminal,
wherein the input signal is input to the first input terminal of the NOR element, the abnormality detection signal is input to the second input terminal of the NOR element, and the clamp operation detection signal is input to the third input terminal of the NOR element,
wherein the output terminal of the NOR element is connected to the input terminal of the filter circuit, and
wherein the control signal is output from the output terminal of the filter circuit.

8. The semiconductor device according to claim 7, wherein the filter circuit filters an output signal from the NOR element and outputs the control signal after a predetermined time.

9. The semiconductor device according to claim 1,
wherein the internal power supply provision circuit includes:
a fifth metal-oxide-semiconductor (MOS) transistor,
a sixth MOS transistor,
a seventh MOS transistor,
an eighth MOS transistor,
a ninth MOS transistor,
a third constant current source,
a fourth constant current source,
a second diode, and
a diode group including a plurality of third diodes connected in series,
wherein each of the fifth, sixth, seventh, eighth and ninth MOS transistors has a gate, a drain, a source and a back gate,
wherein each of the third constant current source and the fourth constant current source has an input terminal and an output terminal,
wherein each of the second diode and the diode group has a cathode and an anode,
wherein the source of the fifth MOS transistor is connected to the back gate of the fifth MOS transistor, the input terminal of the fourth constant current source, the drain of the seventh MOS transistor, and a power supply terminal,
wherein the drain of the fifth MOS transistor is connected to the input terminal of the third constant current source, and the output terminal of the third constant current source is connected to the cathode of the second diode, the gate of the seventh MOS transistor, and the drain of the eighth MOS transistor,
wherein the output terminal of the fourth constant current source is connected to the drain of the sixth MOS transistor, the gate of the eighth MOS transistor, the gate of the ninth MOS transistor, and the cathode of the diode group,
wherein the anode of the second diode is connected to the source of the sixth MOS transistor, the back gate of the sixth MOS transistor, the anode of the diode group, the source of the eighth MOS transistor, the back gate of the eighth MOS transistor, the source of the ninth MOS transistor, the back gate of the ninth MOS transistor, and a ground terminal, and
wherein the control signal is input to the gate of the fifth MOS transistor, an inverted level signal of the control signal is input to the gate of the sixth MOS transistor, and a voltage of the internal power supply is output from a connection node between the source of the seventh MOS transistor and the drain of the ninth MOS transistor.

10. A semiconductor device, comprising:
an output element configured to be connected to a load and to operate the load;
an internal power supply instruction circuit configured
to receive an input signal for performing switching driving of the output element and an abnormality detection signal indicating an abnormal device state of the semiconductor device, and
to output a control signal instructing whether to provide an internal power supply based on the input signal and the abnormality detection signal;
a timer circuit including a timer, the timer circuit being configured to drive the timer in accordance with an instruction of the control signal and to set an output delay of the control signal; and
an internal power supply provision circuit configured to receive the output-delayed control signal from the timer circuit, and to control provision of the internal power supply based on the output-delayed control signal.

11. The semiconductor device according to claim 10, further comprising an internal power supply operation circuit, which includes:
a protection circuit that operates with the internal power supply and outputs the abnormality detection signal upon detecting the abnormal device state, wherein the internal power supply provision circuit provides the internal power supply to the internal power supply operation circuit or stops the provision of the internal power supply to the internal power supply operation circuit.

12. The semiconductor device according to claim 11, wherein the control signal outputted by the internal power supply instruction circuit is:
of a first level to stop the provision of the internal power supply when
both the input signal and the abnormality detection signal indicate an invalid state, and
the timer circuit measures a predetermined time by driving the timer upon receiving the control signal of the first level, and outputs the control signal of the first level after the predetermined time elapses, and
of a second level to instruct the provision of the internal power supply, when
at least one of the input signal or the abnormality detection signal indicates a valid state, and
the timer circuit deactivates the timer to stop the measurement of the predetermined time and outputs the control signal of the second level upon receiving the control signal of the second level.

13. The semiconductor device according to claim 12,
wherein the internal power supply provision circuit stops, upon receiving the control signal of the first level output from the timer circuit after the predetermined time has elapsed, the provision of the internal power supply to the internal power supply operation circuit, to set the internal power supply operation circuit to a standby state, and po1 wherein the internal power supply provision circuit provides, upon receiving the control signal of the second level, the internal power supply to the internal power supply operation circuit, to set the internal power supply operation circuit to an operation state.
